(19) United States
(12) Patent Application Publication
(10) Pub. No.: US 2007/0158702 A1
(43) Pub. Date: Jul. 12, 2007

(54) Transistor including flatband voltage control through interface dipole engineering

(76) Inventors: Mark L. Doczy, Beaverton, OR (US); Matthew V. Metz, Hillsboro, OR (US); Justin K. Brask, Portland, OR (US); Robert S. Chau, Beaverton, OR (US); Gilbert Dewey, Hillsboro, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/322,827

(22) Filed: Dec. 30, 2005

(51) Int. Cl. H01L 29/76; H01L 29/94; H01L 31/00

(52) U.S. Cl. 257/288

(57) ABSTRACT

A transistor comprising a semiconductor including a source, a drain, and a channel interposed between the source and the drain; a first dielectric layer having a first thickness, the first dielectric layer being positioned on the channel; a second dielectric layer having a second thickness, the second dielectric layer being positioned on the first dielectric layer; and a gate electrode on the second dielectric layer, wherein the transistor gate is made of a mid-gap metal. A process comprising depositing a first dielectric layer on at least one surface of a semiconductor layer; depositing a second dielectric layer on the first dielectric layer; depositing a layer of mid-gap metal on the second dielectric layer; and patterning and etching the first dielectric layer, the second dielectric layer and the layer of mid-gap metal to create a gate electrode separated from the substrate by a first dielectric and a second dielectric. Other embodiments are disclosed and claimed.

### TECHNICAL FIELD

The present invention relates generally to semiconductor transistors and in particular, but not exclusively, to semiconductor transistors with improved flatband voltage control.

### BACKGROUND

FIG. 1 illustrates the construction of a planar transistor 100. Transistor 100 includes a substrate 102 on which are formed a semiconductor layer 104, a dielectric layer 110 and a gate electrode 112. Substrate 102 generally includes one or more layers of various well-known insulating substrates such as silicon dioxide, nitrides, oxides, and sapphires. In some embodiments, however, substrate 102 can be a semiconductor, such as but not limited to mono-crystalline silicon substrate and gallium arsenide substrate.

The semiconductor layer 104 includes therein a source 106 and a drain 107, separated from each other by a channel 108. In the illustrated embodiment, the source 106 and drain 107 are n-doped (i.e., doped so that they exhibit n-type conductivity) regions, while the channel 108 is a p-doped region (i.e., doped so that it exhibits p-type conductivity); transistor 100 is thus an n-p-n or NMOS transistor. In other embodiments, however, the semiconductor layer can include a pair of p-doped regions separated from each other by an n-doped region—in other words, a p-n-p or PMOS transistor.

In designing transistor 100, is it desirable to minimize the voltage that must be applied to the gate electrode 112 to cause the transistor 100 to switch states—that is, to switch from on to off or from off to on. One way of minimizing the applied voltage is to select materials for channel 108 and gate electrode 112 that have different work functions W. A material's work function is defined as the amount of energy, measured in electron-volts (eV), needed to move an electron in the solid atom from the Fermi level to vacuum level, i.e., to outside of the atom. Put more simply, a material's work function W is a measure of the energy needed to dislodge an electron from an atom within the material. The work function W is a convenient reference for comparing energy state of various elements and predicting electrical properties of the contact between them.

Current transistor designs aim for an absolute difference of about 1 between the work function of channel 108 and the work function of gate electrode 112. In embodiments of transistor 100 where channel 108 is of p-type conductivity and gate electrode 112 is metal, a work function difference of about 1 means that the metal used for gate electrode 112 should be an n-type metal. N-type metals, however, have two important disadvantages when used in transistors: they are very chemically reactive, and they do not tolerate high temperatures well. During construction of transistor 100, after the gate electrode 112 is formed the transistor 100 must be exposed to one or more high-temperature processes, during which a gate electrode 112 made of n-type metal could melt or could chemically react with dielectric layer 10 or other components.

To deal with the difficulties caused by using n-type metals in gate electrodes, transistor builders have resorted to complex metal replacement processes. In a metal replacement process, transistor 110 is first built with a gate electrode 112 made of a semiconductor or another material that performs well at high temperature. After the transistor is formed and later high-temperature processing is complete, the gate electrode 112 made of semiconductor is etched away and replaced with another gate electrode 112 made of n-type metal. These metal replacement processes, however, are complex, costly, and substantially increase processing time and decrease yield.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a cross-sectional elevation of a planar transistor.

FIG. 2A is a cross-sectional elevation of an embodiment of a planar transistor according to the present invention.

FIG. 2B is an enlargement of the gate, dielectric and well surrounded by the dotted line in FIG. 2A.

FIGS. 3A-3E are cross-sectional elevations of an embodiment of a process flow for producing the embodiment of a planar transistor shown in FIG. 2A.

FIG. 4A is a perspective view of a tri-gate transistor according to the present invention.

FIG. 4B is a cross-sectional elevation of the tri-gate transistor shown in FIG. 4A, taken substantially along the section line B-B.

FIG. 4C is a cross-sectional elevation of the tri-gate transistor shown in FIG. 4A, taken substantially along the section line C-C.

FIG. 5 is a schematic of an embodiment of a system according to the present invention.

### DETAILED DESCRIPTION OF THE ILLUSTRATED EMBODIMENTS

Embodiments of an apparatus and process for a transistor with improved flatband voltage control are described herein. In the following description, numerous specific details are described to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail but are nonetheless encompassed within the scope of the invention. Drawings shown herein are not drawn to scale unless otherwise indicated. All chemical formulas represent the nominal composition of the compounds they represent; compositions that deviate from the listed ones are still within the scope of the invention.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in this specification do not necessarily all refer to the same embodiment. Furthermore, the particular features, structures, or characteristics may be combined in any manner in one or more embodiments.

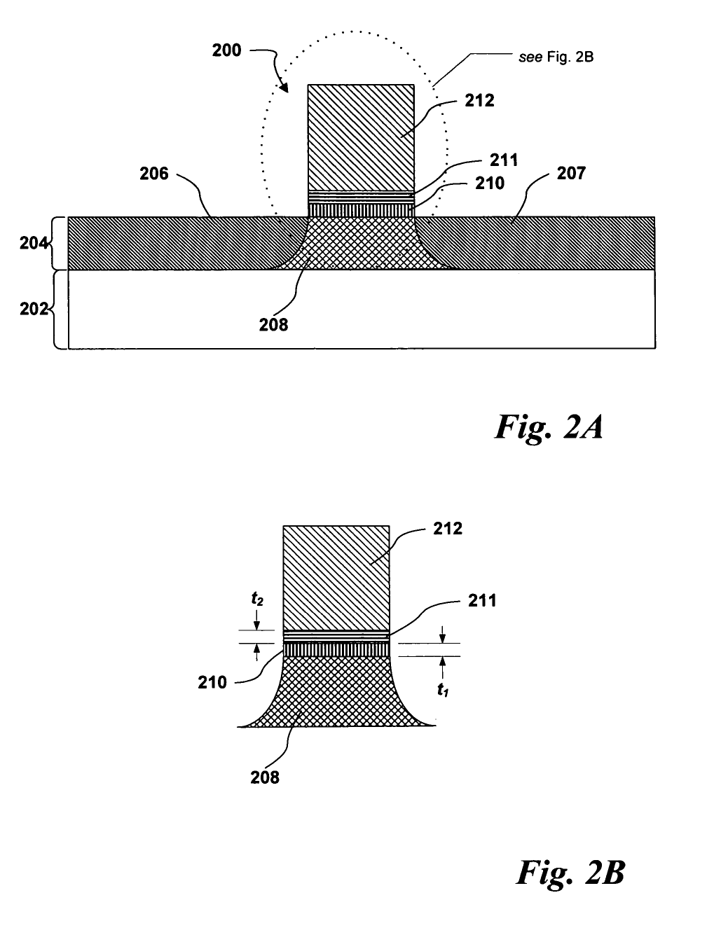

FIGS. 2A-2B illustrate an embodiment of a transistor 200 according to the present invention. As shown in FIG. 2A, transistor 200 includes a substrate 202 on which is formed a semiconductor layer 204. The semiconductor layer 204 includes a source 206 and a drain 207 separated by a channel 208. A transistor gate 212 is separated from channel 208 by a dielectric. The dielectric that separates channel 208 from gate 212 includes at least two layers: a first dielectric layer 210 and a second dielectric layer 211.

In one embodiment of transistor 200, substrate 202 can include one or more layers of any well-known insulating substrate such as silicon dioxide, nitrides, oxides, and sapphires. In other embodiments, the substrate 202 can be a semiconductor, such as but not limited to mono-crystalline silicon (i.e., single-crystal silicon) and gallium arsenide. In still other embodiments, the substrate 202 can include combinations or sub-combinations of layers of insulators, conductors or semiconductors.

The semiconductor layer 204 forms part of the transistor and includes a source 206 and a drain 207 separated from each other by a channel 208. In the illustrated embodiment, the source 206 and drain 207 are n-doped (i.e., doped so that they exhibit n-type conductivity) and are separated from each other by a channel 208 that is p-doped (i.e., doped so that it exhibits p-type conductivity); transistor 200 is thus an n-p-n or NMOS transistor. In other embodiments, however, the semiconductor layer can include a source and drain that are p-doped separated from each other by a channel that is n-doped-in other words, a p-n-p or PMOS transistor.

FIG. 2B further illustrates the details of the gate electrode 212 and the dielectric layers that separate it from the channel 208. The gate electrode 212 is formed using a mid-gap metal. A mid-gap metal is one whose work function falls somewhere between the work function of a p-type metal and the work function of an n-type metal. For example, in one possible classification in which a p-type metal has a work function between 5 and 5.25 eV and an n-type metal has a work function between 4 and 4.25 eV, a mid-gap metal can have a work function between 4.4 and 4.8 eV. As discussed above, a material's work function is a measure of the energy needed to dislodge an electron from an atom within the material. In one embodiment, the mid-gap metal used for gate electrode 212 can be Titanium Nitride (TiN), although in other embodiments other mid-gap metals can be used. Examples of mid-gap metals that can be used in other embodiments of the gate electrode 212 include Tantalum (Ta), Tantalum Nitride (TaN), Tantalum carbide (TaC), Tantalum silicon nitride (TaSiN), Titanium Nitride (TiN), Titanium Silicon Nitride (TiSiN), Hafnium Carbon Silicon Nitride (HfCSiN), Hafnium nitride (HfN), Tungsten (W), Tungsten nitride (WN), Molybdenum (Mo) and Molybdenum nitride (MoN).

Note that, as used herein for the gate electrode 212, the term “metal” includes not only metals in their pure states, but also metal compounds. For example, Titanium (Ti) and Titanium Nitride (TiN) are both metals in the context of this application, even though one is titanium in its pure metallic state and the other is not. Moreover, the term “metal” also need not be limited to a single metal, but can include combinations or alloys of metals, or combinations of alloys of metal compounds.

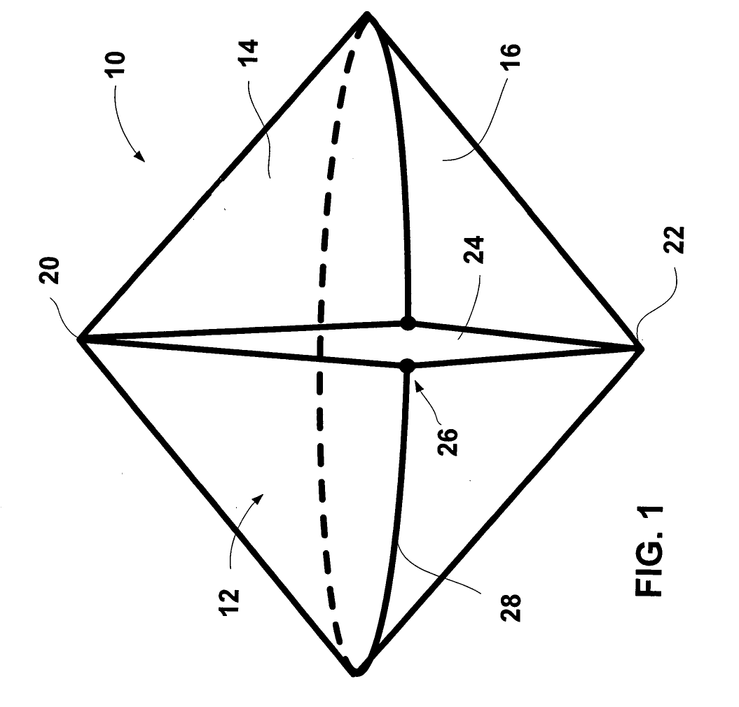

Together, dielectric layers 210 and 211 separate gate electrode 212 from channel 208. Dielectric layer 210 has a thickness t₁ and dielectric layer 211 has a thickness t₂. Generally, the capacitance per unit area of a dielectric is given by the equation:

$$\frac{C}{A} = \frac{k {ɛ}_{0}}{t}$$

where C is the capacitance, A is the area, k is the dielectric factor, ε₀ is the dielectric constant for a vacuum, and t is the thickness of the dielectric. According to the equation, for a given value of k the capacitance per unit area (C/A) is maximized by minimizing the thickness t. If thickness t gets too small, however, current leakage can occur through the dielectric between gate electrode 212 and channel 208. In most transistors, then, the values selected for t₁ and t₂ result from tradeoffs that attempt to maximize capacitance of the combined dielectric layers 210 and 211 while minimizing current or charge leakage. In one embodiment, the overall thickness (t₁+t₂) of the combined dielectric layers will be about the same as the thickness t of the single dielectric layer found in a transistor such as transistor 100 (see FIG. 1). For example, in one embodiment (t₁+t₂) can have a value approximately between 10 and 30 Angstroms, with t₁ having a value approximately between 5 and 20 Angstroms, and t₂ having a value approximately between 3 and 10 Angstroms. Of course, in other embodiments, the value of the sum (t₁+t₂), as well as the individual values of t₁ and t₂, can be greater or lesser, and the ratio of t₁ and t₂ can be different than in the embodiment described.

In one embodiment of the transistor 200, the first dielectric layer 210 has a different dielectric constant (i.e., a different value of k) than the second dielectric layer 211. The first dielectric 210 and second dielectric 211 are also selected such that a dipole will be created in the dielectrics when a voltage is applied to the gate electrode 212. In one embodiment, the first dielectric layer 210 is made of Hafnium Oxide (HfO₂) and the second dielectric layer 211 is made of Yttrium Oxide (Y₂O₃). In other embodiments, of course, the first dielectric layer 210 and the second dielectric layer 211 can be made of other materials. Materials for use in other embodiments of the first dielectric layer include Hafnium Oxide (HfO₂) and Zirconium oxide (ZrO₂). Similarly, materials for use in other embodiments of the second dielectric layer include Lanthanum oxide (La₂O₃), Lanthanum aluminate (LaAlO₃), Scandium oxide (Sc₂O₃), Aluminum oxide (Al₂O₃), and any oxides of metals in the rare earth row of the periodic table, such as Cerium oxide (Ce₂O₃), Praseodymium oxide (Pr₂O₃), Neodymium oxide (Nd₂O₃), Samarium oxide (Sm₂O₃), Europium oxide (Eu₂O₃), Gadolinium oxide (Gd₂O₃), Terbium oxide (Tb₂O₃), Dysprosium oxide (Dy₂O₃), Holmium oxide (Ho₂O₃), Erbium oxide (Er₂O₃), Thulium oxide (Tm₂O₃) and Lutetium oxide (Lu₂O₃).

In operation of the transistor 200, a voltage is applied to the gate electrode 212 to cause the transistor to switch from an off state to an on state. When the voltage is applied to the gate electrode, it results in dipole in dielectric layers 210 and 211, either at the interface between dielectric layers 210 and 211 or at the interface between the gate electrode 212 and the second dielectric layer 211. Along with creating a dipole, the voltage in the gate electrode repels the positive charge carriers (also known as holes) in the p-doped channel 208 until an inversion region is created at the interface between the first dielectric layer 210 and the channel 208. Once the inversion region is created, a negatively charged region connects the source 206 and drain 207 and a current begins to flow between source 206 and drain 207.

Since the gate electrode 212 is made using a mid-gap metal rather than an n-type metal as in transistor 100, the difference in work functions between the channel 208 and the gate electrode 212 is smaller than 1. As a result, one would expect that a higher voltage would need to be applied to gate electrode 212 to operate transistor 200. However, because of the dipole that is induced in the dielectric layers 210 and 211 that separate the channel 208 from the gate electrode 212, the necessary voltage does not increase. Although the dipole does not affect the value of the work function difference between gate electrode 212 and channel 208, in essence it increases the effective value of the work function. In other words, to the charge carriers in the channel 208, the work function difference can appear larger that it actually is. The result is that little or no additional voltage is necessary to operate the transistor, even though the work function difference is smaller.

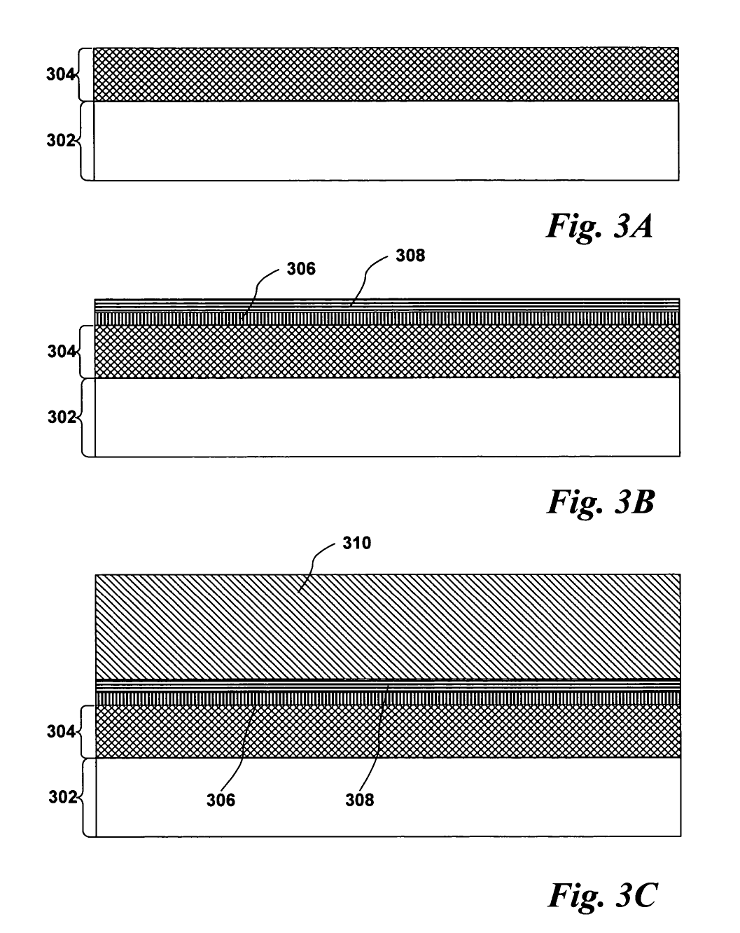

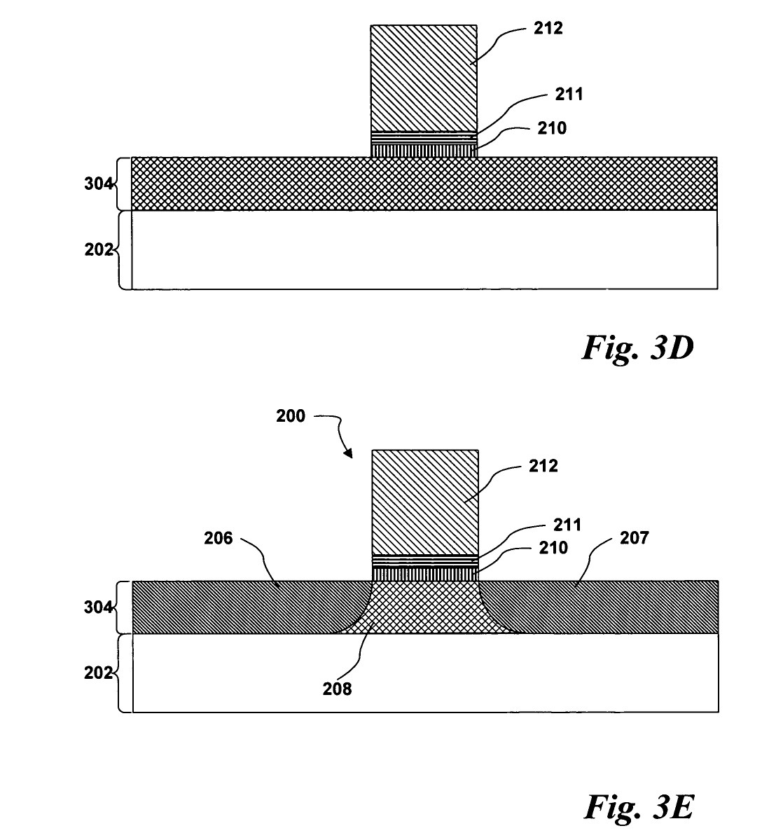

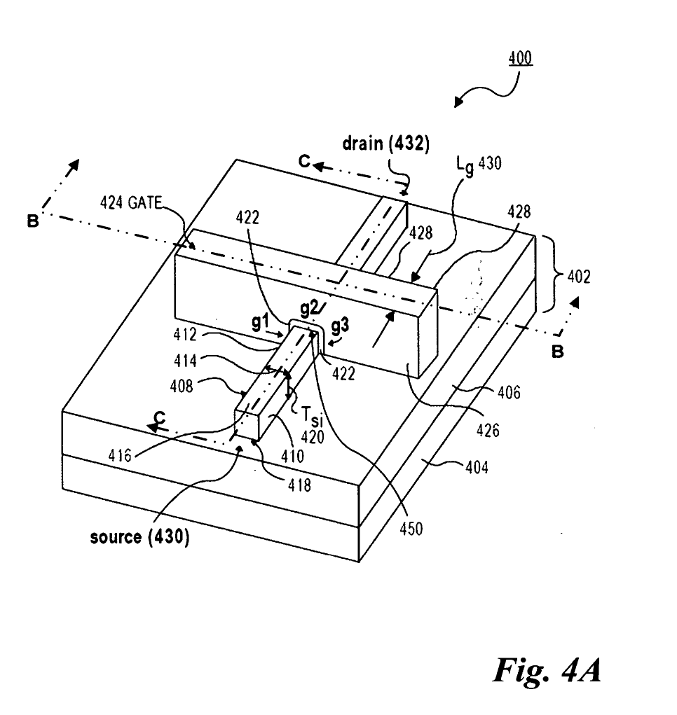

FIGS. 3A-3E illustrate an embodiment of a process for building transistor 200. FIG. 3A begins the process with a substrate 302 on which a layer of doped semiconductor 304 is deposited. As described above, substrate 302 can include one or more layers of any well-known insulating substrate such as silicon dioxide, nitrides, oxides, and sapphires. In other embodiments, the substrate 302 can be a semiconductor, such as but not limited to mono-crystalline silicon (i.e., single-crystal silicon) and gallium arsenide. In still other embodiments, the substrate 302 can include combinations or sub-combinations of layers of insulators, conductors or semiconductors.

The doped semiconductor layer 304 is a layer of semiconductor that is either p-doped or n-doped, although the dopant concentration need not be uniform throughout the layer 304. The doping of semiconductor layer 304 is selected to be the same as the doping of channel 208 in the resulting transistor 200. For example, in the embodiment shown in FIG. 2A transistor 200 is a n-p-n transistor where channel 208 is p-doped. To, create transistor 200, then, semiconductor layer 304 should be a p-doped layer. In another embodiment where the transistor includes a channel that is n-doped semiconductor layer 304 should be an n-doped layer.

FIG. 3B illustrates the substrate 302 and semiconductor layer 304 after a first dielectric layer 306 has been deposited on the surface of the semiconductor layer 304 and after a second dielectric layer 308 has been deposited on the surface of the first dielectric layer 306. The first dielectric layer 306 and second dielectric layer 308 can be deposited by various methods, including physical vapor deposition (PVD) methods such as thermal evaporation or sputtering, chemical vapor deposition (CVD) methods wherein the solid product of a chemical reaction is deposited on the surface of the substrate, and atomic layer deposition (ALD) methods. The choice of method for depositing first dielectric layer 306 and second dielectric layer 308 will generally depend on the particular dielectric materials being deposited, as well as on the topography of the surface on which the dielectrics are deposited.

FIG. 3C illustrates the build-up of the layers after deposition of layer 310 of mid-gap metal. Starting with the build-up as it is shown in FIG. 3B, a layer of mid-gap metal 310 is deposited on the surface of the second dielectric layer 308. The layer of mid-gap metal 310 can be deposited by various methods, including physical vapor deposition (PVD) methods such as thermal evaporation or sputtering, chemical vapor deposition (CVD) methods in which deposited species are formed as a results of chemical reaction between gaseous reactants at elevated temperature in the vicinity of the substrate and the solid product of the reaction is deposited on the surface of the substrate, and atomic layer deposition (ALD) methods. The choice of method for depositing the mid-gap metal layer 310 will generally depend on the particular mid-gap metal being deposited, as well as on the characteristics of the dielectric layer 308 on which the metal is deposited. For example, in some embodiments dielectric layer 308 could be too delicate to withstand deposition of the mid-gap metal layer 310 by sputtering; in such cases, CVD or ALD methods may be a better choice.

FIG. 3D illustrates the transistor build-up after etching. Starting with the build-up as it is shown in FIG. 3C, the mid-gap metal layer is first patterned to define the gate electrode 212. After the gate electrode 212 is defined, the build-up is etched to remove those regions of the mid-gap metal layer 310 that may not become part of the gate electrode 212. As part of the same etch or a different etch, the second dielectric layer 308 and the first dielectric 306 are etched away from the field surrounding the gate electrode 212, leaving first dielectric layer 210 and second dielectric layer 211, which are the portions of the dielectric layers 306 and 308 that remain between the gate electrode 212 and the semiconductor layer 304 after etching.

FIG. 3E illustrates the transistor build-up after doping that creates source 206 and drain 207 in semiconductor layer 304. Starting with the transistor build-up shown in FIG. 3D, the entire build-up is brought to high temperature and bombarded from above with doping particles, the aim being to form source 206 and drain 207 by reversing the doping of semiconductor layer 304 in the regions adjacent to the gate electrode 212. The doping of the region of the semiconductor layer that lies beneath the gate electrode does not change because it is shielded by the gate electrode from bombardment by doping particles. Thus, channel 208 retains the same conductivity type (p-type or n-type) as the original semiconductor layer 304. As the conclusion of doping, the result is the transistor 200.

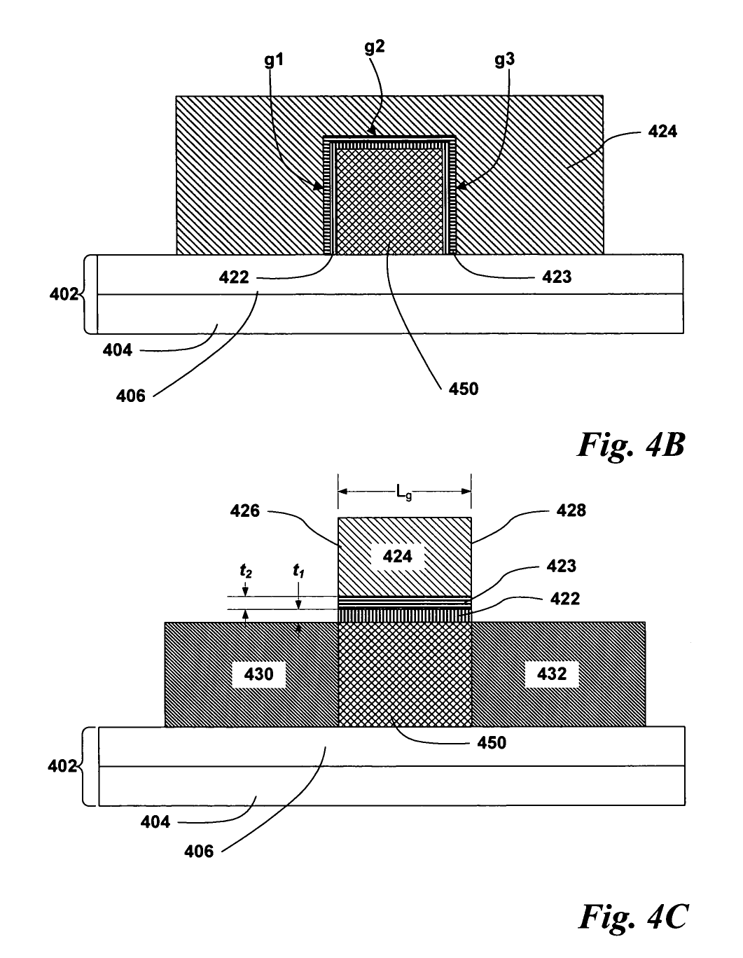

FIG. 4A illustrates an embodiment of a tri-gate transistor 400 according to the present invention. Tri-gate transistor 400 is formed on a substrate 402 that includes a lower mono-crystalline silicon substrate 404 upon which is formed in insulating layer 406, such as a silicon dioxide film. In other embodiments, the substrate 402 can include one or more layers of any well-known insulating substrate such as silicon dioxide, nitrides, oxides, and sapphires. In other embodiments, the substrate 402 can include one or more layers of a semiconductor, such as but not limited to mono-crystalline silicon (i.e., single-crystal silicon) and gallium arsenide. In still other embodiments, the substrate 202 can include combinations or sub-combinations of layers of insulators, conductors or semiconductors.

Tri-gate transistor 400 includes a transistor body 408 formed on insulator 406 of insulating substrate 402. Transistor body 408 includes a pair of sidewalls 410 and 412 separated by a distance that defines a transistor body width 414. Transistor body 408 also has a top surface 416, as well as a bottom surface 418 that is formed on insulator 406; the distance between the top surface 416 and the bottom surface 418 defines a body height 420. In one embodiment of the present invention the body height 420 can vary from approximately ½ to approximately 2 times the body width 414. In other embodiments, of course, body height 420 and body width 414 can have a ratio that is higher or lower. Transistor body 408 can be formed of any well-known material which can be reversibly altered from an insulating state to a conductive state by applying external electrical controls. Transistor body 408 can be formed of any well-known semiconductor material, such as but not limited to silicon (Si), germanium (Ge), silicon germanium (SiₓGe_{y}), gallium arsenide (GaAs), InSb, GaP, GaSb and carbon nanotubes.

FIG. 4B further illustrates the construction of tri-gate transistor 400. Tri-gate transistor 400 includes at least two dielectric layers: a first dielectric layer 422 and a second dielectric layer 423. First dielectric layer 422 is formed on and around three sides of transistor body 408: dielectric layer 422 is formed on or adjacent to sidewall 412, on top surface 416 and on or adjacent to sidewall 410 of body 408. Second dielectric layer 423 is formed on and around the three sides of the first dielectric layer 422 and has substantially the same shape as the first dielectric layer 422. First dielectric layer 422 has a thickness tᵢ and second dielectric layer 423 has a thickness t₂. As in transistor 200, the values selected for t₁ and t₂ result from tradeoffs that attempt to maximize capacitance of the combined dielectric layers 422 and 423 while minimizing current or charge leakage. In one embodiment, the overall thickness (t₁+t₂) can have a value approximately between 10 and 30 Angstroms, with t₁ having a value approximately between 5 and 20 Angstroms, and t₂ having a value approximately between 3 and 10 Angstroms. Of course, in other embodiments, the value of the sum (t₁+t₂), as well as the individual values of t₁ and t₂, can be greater or lesser, and the ratio of t₁ and t₂ can be different than in the embodiment described.

In one embodiment of the transistor 400, the first dielectric layer 422 has a different dielectric constant (i.e., a different value of k) than the second dielectric layer 423. The first dielectric 422 and second dielectric 423 are also selected such that a dipole will be created in the dielectrics when a voltage is applied to the gate electrode 424. In one embodiment, the first dielectric layer 422 is made of Hafnium Oxide (HfO₂) and the second dielectric layer 423 is made of Yttrium Oxide (Y₂O₃). In other embodiments, of course, the first dielectric layer 422 and the second dielectric layer 423 can be made of other materials. Materials for use in other embodiments of the first dielectric layer 422 include Hafnium Oxide (HfO₂) and Zirconium oxide (ZrO₂). Similarly, materials for use in other embodiments of the second dielectric layer 423 include substantially the same materials discussed above in connection with the second dielectric layer 211.

Tri-gate transistor 400 also includes a gate electrode 424 formed on and around second dielectric layer 423. Gate electrode 424 includes a pair of laterally opposite sidewalls 426 and 428 separated by a distance that defines the gate length (Lg) 430 of transistor 400 (see FIG. 4C). In an embodiment of the present invention the laterally opposite sidewalls 426 and 428 of the gate electrode 424 are perpendicular to the laterally opposite sidewalls 410 and 412 of transistor body 408.

As in transistor 200, gate electrode 424 is formed using a mid-gap metal. As noted above, a mid-gap metal is one whose work function falls somewhere between the work function of a p-type metal and the work function of an n-type metal. For example, in one possible classification in which a p-type metal has a work function between 5 and 5.25 eV and an n-type metal has a work function between 4 and 4.25 eV, a mid-gap metal can have a work function between 4.4 and 4.8 eV. In one embodiment, the mid-gap metal used for gate electrode 424 can be Titanium Nitride (TiN), although in other embodiments other mid-gap metals can be used. Examples of mid-gap metals that can be used in other embodiments of the gate electrode 212 include Tantalum (Ta), Tantalum Nitride (TaN), Tantalum carbide (TaC), Tantalum silicon nitride (TaSiN), Titanium Nitride (TiN), Titanium Silicon Nitride (TiSiN), Hafnium Carbon Silicon Nitride (HfCSiN), Hafnium nitride (HfN), Tungsten (W), Tungsten nitride (WN), Molybdenum (Mo) and Molybdenum nitride (MoN).

Note that, as used herein for the gate electrode 424, the term “metal” not only includes metals in their pure states, but also includes metal compounds. For example, Titanium (Ti) and Titanium Nitride (TiN) are both metals in the context of this application, even though one is titanium in its pure state and the other is not. Moreover, the term “metal” also need not be limited to a single metal, but can include combinations or alloys of metals, or combinations of alloys of metal compounds.

FIG. 4C illustrates in more detail the construction of the transistor body 408. Transistor body 408 includes a source region 430 and a drain region 432 formed on opposite sides of gate electrode 424. Source region 430 and drain region 432 are formed of the same conductivity type such as n-type or p-type conductivity. Source region 430 and drain region 432 can be formed of uniform concentration or can include subregions of different concentrations or doping profiles such as tip regions (e.g., source/drain extensions). The portion of transistor body 408 located between source region 430 and drain region 432 defines the channel region 450. The channel region 450 can also be defined as the area of the transistor body 408 surrounded by the gate electrode 424. At times however, the source/drain region may extend slightly beneath the gate electrode through, for example, diffusion to define a channel region slightly smaller than the gate electrode length (Lg). In an embodiment of the present invention, when the channel region is doped it is typically doped to the opposite conductivity type of the source region 430 and the drain region 432. For example, when the source and drain regions are n-type conductivity the channel region would be doped to p-type conductivity. Similarly, when the source and drain regions are p-type conductivity the channel region would be n-type conductivity. In this manner a tri-gate transistor 400 can be formed into either a NMOS transistor or a PMOS transistor respectively. Channel region 450 can be uniformly doped or can be doped non-uniformly or with differing concentrations to provide particular electrical and performance characteristics.

By providing first dielectric 422, second dielectric layer 423 gate electrode 424, all of which surround the transistor body on three sides, the tri-gate transistor is characterized in having three channels and three gates, one (g1) along side 412 of transistor body 408, a second (g2) along the top surface 416 of transistor body 408, and the third (g3) along the sidewall 410 of transistor body 408. The effective gate width (Gw) of transistor 400 is the sum of the widths of the three channel regions. That is, the gate width of transistor 400 is equal to the height 420 of transistor body 408 at sidewall 410, plus the width of transistor body of 408 at the top surface 416, plus the height 420 of transistor body 408 at sidewall 412.

Because the channel region 450 is surrounded on three sides by gate electrode 424 and gate dielectric 422, transistor 400 can be operated in a fully depleted manner wherein when transistor 400 is turned on the channel region 450 fully depletes thereby providing the advantageous electrical characteristics and performance of a fully depleted transistor. That is, when transistor 400 is turned on a depletion region is formed in channel region 450 along with an inversion layer at the surfaces of region 450 (i.e., an inversion layer is formed on the side surfaces and top surface of the transistor body). The inversion layer has the same conductivity type as the source and drain regions and forms a conductive channel between the source and drain regions to allow current to flow therebetween.

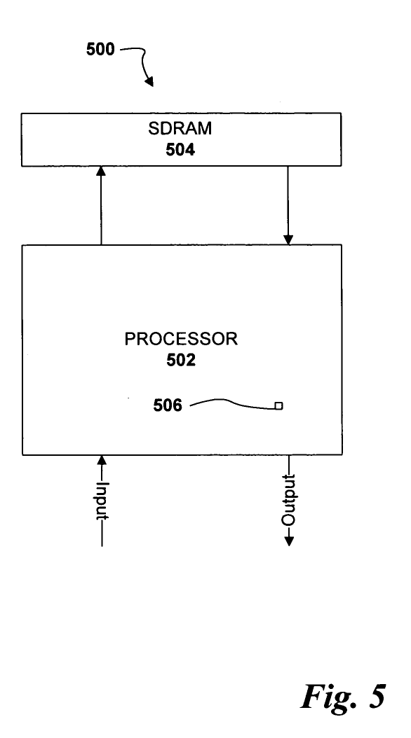

FIG. 5 illustrates a system 500 according to the present invention. In the system 500, a processor 502 is coupled to a memory such as SDRAM 504 with which it exchanges data while performing operations. The processor 502 also includes an input and an output through which the processor 502 receives data from and transmits data to other components with which the processor 502 can be connected. Within the processor 502 are one or more transistors 506. In one embodiment, the transistor 506 can be a planar transistor such as transistor 200, while in other embodiments the transistor 506 can be a tri-gate transistor such as transistor 400.

The above description of illustrated embodiments of the invention, including what is described in the abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. These modifications can be made to the invention in light of the above detailed description.

The terms used in the following claims should not be construed to limit the invention to the specific embodiments disclosed in the specification and the claims. Rather, the scope of the invention is to be determined by the following claims, which are to be construed in accordance with established doctrines of claim interpretation.

1. A transistor comprising:
a semiconductor including a source, a drain, and a channel interposed between the source and the drain;
a first dielectric layer having a first thickness, the first dielectric layer being positioned on the channel;
a second dielectric layer having a second thickness, the second dielectric layer being positioned on the first dielectric layer; and
a gate electrode on the second dielectric layer, wherein the transistor gate is made of a mid-gap metal.

2. The transistor of claim 1 wherein the first thickness is greater than the second thickness.

3. The transistor of claim 1 wherein a dipole is created in the first dielectric layer or the second dielectric layer when a voltage is applied to the gate electrode.

4. The transistor of claim 1 wherein the first dielectric layer includes one or more of Hafnium Oxide (HfO₂) and Zirconium oxide (ZrO₂).

5. The transistor of claim 1 wherein the second dielectric layer includes one or more of Yttrium Oxide (Y₂O₃), Lanthanum oxide (La₂O₃), Lanthanum aluminate (LaAlO₃), Scandium oxide (Sc₂O₃), Aluminum oxide (Al₂O₃), Cerium oxide (Ce₂O₃), Praseodymium oxide (Pr₂O₃), Neodymium oxide (Nd₂O₃), Samarium oxide (Sm₂O₃), Europium oxide (Eu₂O₃), Gadolinium oxide (Gd₂O₃), Terbium oxide (Tb₂O₃), Dysprosium oxide (Dy₂O₃), Holmium oxide (Ho₂O₃), Erbium oxide (Er₂O₃), Thulium oxide (Tm₂O₃) and Lutetium oxide (Lu₂O₃).

6. The transistor of claim 1 wherein the mid-gap metal includes one or more of Tantalum (Ta), Tantalum Nitride (TaN), Tantalum carbide (TaC), Tantalum silicon nitride (TaSiN), Titanium Nitride (TiN), Titanium Silicon Nitride (TiSiN), Hafnium Carbon Silicon Nitride (HfCSiN), Hafnium nitride (HfN), Tungsten (W), Tungsten nitride (WN), Molybdenum (Mo) and Molybdenum nitride (MoN).

7. The transistor of claim 1 wherein the transistor is a planar transistor.

8. A system comprising:
an SDRAM memory; and
a processor coupled to the SDRAM memory, the processor including at least one transistor comprising:
a semiconductor including a source, a drain and a channel interposed between the source and drain;
a first dielectric layer positioned adjacent to the channel;
a second dielectric layer positioned on the first dielectric layer;
a gate electrode deposited on the second dielectric layer, wherein the transistor gate is made of a mid-gap metal.

9. The system of claim 8 wherein the second dielectric layer is thinner than the first dielectric layer.

10. The system of claim 8 wherein a dipole is created in the first or second dielectric layers when a current is applied to the transistor gate.

11. The system of claim 8 wherein the first dielectric layer includes one or more of Hafnium Oxide (HfO₂) and Zirconium oxide (ZrO₂).

12. The system of claim 8 wherein the second dielectric layer includes one or more of Yttrium Oxide (Y₂O₃), Lanthanum oxide (La₂O₃), Lanthanum aluminate (LaAlO₃), Scandium oxide (Sc₂O₃), Aluminum oxide (Al₂O₃), Cerium oxide (Ce₂O₃), Praseodymium oxide (Pr₂O₃), Neodymium oxide (Nd₂O₃), Samarium oxide (Sm₂O₃), Europium oxide (Eu₂O₃), Gadolinium oxide (Gd₂O₃), Terbium oxide (Tb₂O₃), Dysprosium oxide (Dy₂O₃), Holmium oxide (Ho₂O₃), Erbium oxide (Er₂O₃), Thulium oxide (Tm₂O₃) and Lutetium oxide (Lu₂O₃).

13. The system of claim 8 wherein the mid-gap metal includes one or more of Tantalum (Ta), Tantalum Nitride (TaN), Tantalum carbide (TaC), Tantalum silicon nitride (TaSiN), Titanium Nitride (TiN), Titanium Silicon Nitride (TiSiN), Hafnium Carbon Silicon Nitride (HfCSiN), Hafnium nitride (HfN), Tungsten (W), Tungsten nitride (WN), Molybdenum (Mo) and Molybdenum nitride (MoN).

14. The system of claim 8 wherein the transistor is a planar transistor.

15. A process comprising:
depositing a first dielectric layer on at least one surface of a semiconductor layer;
depositing a second dielectric layer on the first dielectric layer;
depositing a layer of mid-gap metal on the second dielectric layer; and
patterning and etching the first dielectric layer, the second dielectric layer and the layer of mid-gap metal to create a gate electrode separated from the substrate by a first dielectric and a second dielectric.

16. The process of claim 15 wherein the semiconductor layer exhibits p-type conductivity.

17. The process of claim 15 further comprising doping the semiconductor layer to create a source and a drain in the semiconductor layer adjacent to and on opposite sides of the gate electrode and a channel in the semiconductor layer under the gate electrode.

18. The process of claim 15 wherein depositing the layer of mid-gap metal comprises depositing using physical vapor deposition (PVD), chemical vapor deposition (CVD) or atomic layer deposition (ALD).

19. The process of claim 15 wherein the first dielectric layer includes one or more of Hafnium Oxide (HfO₂) and Zirconium oxide (ZrO₂).

20. The process of claim 15 wherein the second dielectric layer includes one or more of Yttrium Oxide (Y₂O₃), Lanthanum oxide (La₂O₃), Lanthanum aluminate (LaAlO₃), Scandium oxide (Sc₂O₃), Aluminum oxide (Al₂O₃), Cerium oxide (Ce₂O₃), Praseodymium oxide (Pr₂O₃), Neodymium oxide (Nd₂O₃), Samarium oxide (Sm₂O₃), Europium oxide (Eu₂O₃), Gadolinium oxide (Gd₂O₃), Terbium oxide (Tb₂O₃), Dysprosium oxide (Dy₂O₃), Holmium oxide (Ho₂O₃), Erbium oxide (Er₂O₃), Thulium oxide (Tm₂O₃) and Lutetium oxide (Lu₂O₃).

21. The process of claim 15 wherein the mid-gap metal includes one or more of Tantalum (Ta), Tantalum Nitride (TaN), Tantalum carbide (TaC), Tantalum silicon nitride (TaSiN), Titanium Nitride (TiN), Titanium Silicon Nitride (TiSiN), Hafnium Carbon Silicon Nitride (HfCSiN), Hafnium nitride (HfN), Tungsten (W), Tungsten nitride (WN), Molybdenum (Mo) and Molybdenum nitride (MoN).
